(19) United States
(12) Patent Application Publication
(10) Pub. No.: US 2023/0343914 A1
(43) Pub. Date: Oct. 26, 2023

(54) Display with Side-Wrapped Conductive Traces

(71) Applicant: Apple Inc., Cupertino, CA (US)

(72) Inventors: Han-Chieh Chang, Sunnyvale, CA (US); Anshi Liang, Saratoga, CA (US); Arnoldus A Barlian, San Francisco, CA (US); Bayu A Thedjoisworo, San Jose, CA (US); Boris A Russ, Mountain View, CA (US); Chun-Lan Wu, Sunnyvale, CA (US); Ken Hsuan Liao, San Jose, CA (US); Marc J DeVincentis, Palo Alto, CA (US); Meng-Tse Chen, Hsinchu (TW); Nathan K Gupta, Hillsborough, CA (US); Paolo Sacchetto, Cupertino, CA (US); Paul S Drzaic, Morgan Hill, CA (US); Po-Jui Chen, Cupertino, CA (US); Ying-Chih Wang, Sunnyvale, CA (US); Yong Sun, San Jose, CA (US); Zhen Zhang, Sunnyvale, CA (US); Ziyang Zhang, Woodland Hills, CA (US)

(21) Appl. No.: 18/185,237

(22) Filed: Mar. 16, 2023

Related U.S. Application Data
(60) Provisional application No. 63/334,546, filed on Apr. 25, 2022.

(51) Int. Cl. H01L 33/62; H01L 27/15; H01L 33/48

(52) U.S. Cl. CPC H01L 33/62; H01L 27/156; H01L 33/486

(57) ABSTRACT

Conductive traces may be conformally wrapped around the side of a display panel that includes an array of display pixels. The conductive traces may electrically connect contacts on an upper surface of the display panel to corresponding contacts on a flexible printed circuit that is attached to a lower surface of the display panel. The side-wrapped conductive traces may be interposed between first and second insulating layers. The flexible printed circuit may have a multi-step interface that is electrically connected to the side-wrapped conductive traces. A system-in-package including a display driver integrated circuit may be mounted to the flexible printed circuit. The system-in-package may include a plurality of redistribution layers that electrically connect contacts on the display driver integrated circuit to contacts on the flexible printed circuit.

This application claims the benefit of U.S. Provisional Patent Application No. 63/334,546, filed Apr. 25, 2022, which is hereby incorporated by reference herein in its entirety.

### BACKGROUND

This relates generally to electronic devices, and, more particularly, to electronic devices with displays.

Electronic devices often include displays. For example, an electronic device may have an organic light-emitting diode (OLED) display based on organic light-emitting diode pixels or a liquid crystal display (LCD) based on liquid crystal display pixels.

Electronic devices may include control circuitry that is configured to provide control signals to pixels in a display. If care is not taken, the components used to provide control signals to pixels in a display may be more bulky than desired and/or less robust than desired.

### SUMMARY

An electronic device may have a display with an array of display pixels. The display pixels may be organic light-emitting diode (OLED) display pixels, microLED display pixels, or other types of display pixels. The display may be flexible and/or may have curved portions.

To provide control signals to the display pixels, conductive traces may be conformally wrapped around the side of a display panel that includes the array of display pixels. The conductive traces may electrically connect contacts on an upper surface of the display panel to corresponding contacts on a flexible printed circuit that is attached to a lower surface of the display panel. The side-wrapped conductive traces may be interposed between first and second insulating layers.

The flexible printed circuit may have a multi-step interface that is electrically connected to the side-wrapped conductive traces. A first subset of the side-wrapped conductive traces may be electrically connected to contacts on an exposed portion of a first layer of the flexible printed circuit. A second subset of the side-wrapped conductive traces may pass through the exposed portion of the first layer of the flexible printed circuit to be electrically connected to contacts on a second layer of the flexible printed circuit.

A system-in-package including a display driver integrated circuit may be mounted to the flexible printed circuit. The system-in-package may include a plurality of redistribution layers that electrically connect contacts on the display driver integrated circuit to contacts on the flexible printed circuit.

### BRIEF DESCRIPTION OF THE DRAWINGS

FIG. 1 is a schematic diagram of an illustrative electronic device having a display in accordance with various embodiments.

FIG. 2 is a schematic diagram of an illustrative display in accordance with various embodiments.

FIG. 3 is a schematic diagram of an illustrative display with pixel control circuits in accordance with various embodiments.

FIG. 4 is a schematic diagram of an illustrative passive matrix of light-emitting diodes that is controlled by a pixel control circuit in accordance with various embodiments.

FIG. 5 is a cross-sectional side view of an illustrative display with side-wrapped conductive traces in accordance with various embodiments.

FIG. 6 is a top view of an illustrative display with contacts that are distributed around the periphery of the display in accordance with various embodiments.

FIG. 7 is a cross-sectional side view of an illustrative flexible printed circuit with a multi-step interface in accordance with various embodiments.

FIG. 8 is a bottom view of the illustrative flexible printed circuit of FIG. 7 in accordance with various embodiments.

FIG. 9 is a cross-sectional side view of an illustrative display with side-wrapped conductive traces and a planarization layer that forms a dam structure in accordance with various embodiments.

FIG. 10A is a cross-sectional side view of an illustrative display with side-wrapped conductive traces and a planarization layer that forms channels for the side-wrapped conductive traces in accordance with various embodiments.

FIG. 10B is a cross-sectional side view of the illustrative channels and corresponding conductive traces of FIG. 10A in accordance with various embodiments.

FIG. 11 is a flowchart of illustrative method steps for forming conductive traces between first and second insulating layers in accordance with various embodiments.

FIG. 12 is a flowchart of illustrative method steps for forming conductive traces in channels between first and second insulating layers in accordance with various embodiments.

FIG. 13 is a cross-sectional side view of an illustrative system-in-package with a display driver integrated circuit that may be included in a display of the type shown in FIG. 5 in accordance with various embodiments.

### DETAILED DESCRIPTION

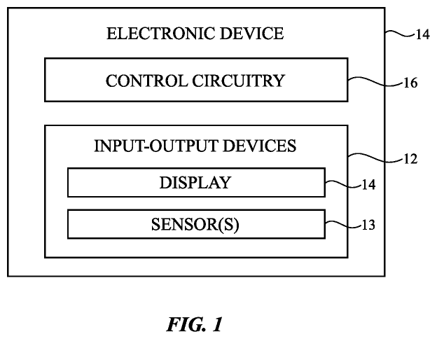

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user.

As shown in FIG. 1, electronic device 10 may include control circuitry 16 for supporting the operation of device 10. Control circuitry 16 may include storage such as hard disk drive storage, nonvolatile memory (e.g., flash memory or other electrically-programmable-read-only memory configured to form a solid-state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application-specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input resources of input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the display pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

Input-output devices 12 may also include one or more sensors 13 such as force sensors (e.g., strain gauges, capacitive force sensors, resistive force sensors, etc.), audio sensors such as microphones, touch and/or proximity sensors such as capacitive sensors (e.g., a two-dimensional capacitive touch sensor associated with a display and/or a touch sensor that forms a button, trackpad, or other input device not associated with a display), and other sensors. In accordance with some embodiments, sensors 13 may include optical sensors such as optical sensors that emit and detect light (e.g., optical proximity sensors such as transreflective optical proximity structures), ultrasonic sensors, and/or other touch and/or proximity sensors, monochromatic and color ambient light sensors, image sensors (cameras), fingerprint sensors, temperature sensors, proximity sensors and other sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 13 and/or other input-output devices to gather user input (e.g., buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.).

Display 14 may be an organic light-emitting diode display, a display formed from an array of discrete light-emitting diodes (microLEDs) each formed from a crystalline semiconductor die, a liquid crystal display, or any other suitable type of display. Device configurations in which display 14 includes microLEDs are sometimes described herein as an example. This is, however, merely illustrative. Any suitable type of display may be used, if desired. In general, display 14 may have a rectangular shape (i.e., display 14 may have a rectangular footprint and a rectangular peripheral edge that runs around the rectangular footprint) or may have other suitable shapes. Display 14 may be planar or may have a curved profile.

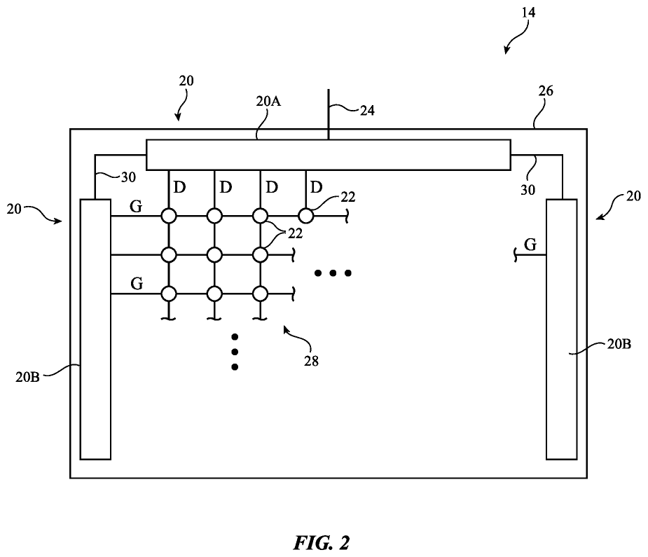

FIG. 2 is a diagram of an illustrative display. The display of FIG. 2 is an active matrix display. As shown in FIG. 2, display 14 may include layers such as substrate layer 26. Substrate layers such as layer 26 may be formed from rectangular planar layers of material or layers of material with other shapes (e.g., circular shapes or other shapes with one or more curved and/or straight edges). The substrate layers of display 14 may include glass layers, polymer layers, silicon layers, composite films that include polymer and inorganic materials, metallic foils, etc.

Display 14 may have an array of pixels 22 for displaying images for a user such as pixel array 28. Pixels 22 (e.g., microLEDs) in array 28 may be arranged in rows and columns. The edges of array 28 may be straight or curved (i.e., each row of pixels 22 and/or each column of pixels 22 in array 28 may have the same length or may have a different length). There may be any suitable number of rows and columns in array 28 (e.g., ten or more, one hundred or more, or one thousand or more, etc.). Display 14 may include pixels 22 of different colors. As an example, display 14 may include red pixels, green pixels, and blue pixels.

Display driver circuitry 20 may be used to control the operation of pixels 22. Display driver circuitry 20 may be formed from integrated circuits, thin-film transistor circuits, and/or other suitable circuitry. Illustrative display driver circuitry 20 of FIG. 2 includes display driver circuitry 20A and additional display driver circuitry such as gate driver circuitry 20B. Gate driver circuitry 20B may be formed along one or more edges of display 14. For example, gate driver circuitry 20B may be arranged along the left and right sides of display 14 as shown in FIG. 2.

As shown in FIG. 2, display driver circuitry 20A (e.g., one or more display driver integrated circuits, thin-film transistor circuitry, etc.) may contain communications circuitry for communicating with system control circuitry over signal path 24. Path 24 may be formed from traces on a flexible printed circuit or other cable. The control circuitry may be located on one or more printed circuits in electronic device 10. During operation, control circuitry (e.g., control circuitry 16 of FIG. 1) may supply circuitry such as a display driver integrated circuit in circuitry 20 with image data for images to be displayed on display 14. Display driver circuitry 20A of FIG. 2 is located at the top of display 14. This is merely illustrative. Display driver circuitry 20A may be located at both the top and bottom of display 14 or in other portions of device 10.

To display the images on pixels 22, display driver circuitry 20A may supply corresponding image data to data lines D while issuing control signals to supporting display driver circuitry such as gate driver circuitry 20B over signal paths 30. With the illustrative arrangement of FIG. 2, data lines D run vertically through display 14 and are associated with respective columns of pixels 22.

Gate driver circuitry 20B (sometimes referred to as gate line driver circuitry or horizontal control signal circuitry) may be implemented using one or more integrated circuits and/or may be implemented using thin-film transistor circuitry on substrate 26. Horizontal control lines G (sometimes referred to as gate lines, scan lines, emission control lines, etc.) run horizontally through display 14. Each gate line G is associated with a respective row of pixels 22. If desired, there may be multiple horizontal control lines such as gate lines G associated with each row of pixels. Individually controlled and/or global signal paths in display 14 may also be used to distribute other signals (e.g., power supply signals, etc.).

Gate driver circuitry 20B may assert control signals on the gate lines G in display 14. For example, gate driver circuitry 20B may receive clock signals and other control signals from circuitry 20A on paths 30 and may, in response to the received signals, assert a gate line signal on gate lines G in sequence, starting with the gate line signal G in the first row of pixels 22 in array 28. As each gate line is asserted, data from data lines D may be loaded into a corresponding row of pixels. In this way, control circuitry such as display driver circuitry 20A and 20B may provide pixels 22 with signals that direct pixels 22 to display a desired image on display 14. Each pixel 22 may have a light-emitting diode and circuitry (e.g., thin-film circuitry on substrate 26) that responds to the control and data signals from display driver circuitry 20.

Gate driver circuitry 20B may include blocks of gate driver circuitry such as gate driver row blocks. Each gate driver row block may include circuitry such output buffers and other output driver circuitry, register circuits (e.g., registers that can be chained together to form a shift register), and signal lines, power lines, and other interconnects. Each gate driver row block may supply one or more gate signals to one or more respective gate lines in a corresponding row of the pixels of the array of pixels in the active area of display 14.

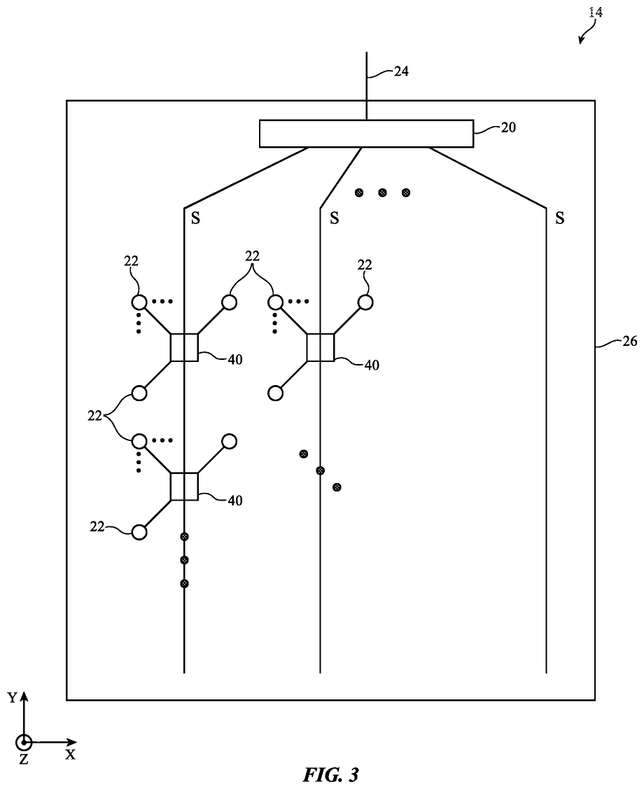

The active matrix addressing scheme of FIG. 2 is merely illustrative. If desired, display 14 may instead use pixel control circuits that address local passive matrices of pixels. An example of this type is shown in FIG. 3. As shown in FIG. 3, display 14 again may include layers such as substrate layer 26. Layers such as substrate 26 may be formed from layers of material such as glass layers, polymer layers, composite films that include polymer and inorganic materials, metallic foils, semiconductors such as silicon or other semiconductor materials, layers of material such as sapphire (e.g., crystalline transparent layers, ceramics, etc.), or other material. Substrate 26 may optionally be transparent (e.g., having a transparency greater than 80%, greater than 85%, greater than 90%, greater than 95%, greater than 98%, greater than 99%, etc.). Substrate 26 may be planar or may have other shapes (e.g., concave shapes, convex shapes, shapes with planar and curved surface regions, etc.). The outline of substrate 26 (e.g., when viewed from above along the Z-direction) may be circular, oval, rectangular, square, may have a combination of straight and curved edges, or may have other suitable shapes. As shown in the rectangular substrate example of FIG. 3, substrate 26 may have left and right vertical edges and upper and lower horizontal edges.

Display 14 may have an array of pixels 22 for displaying images for a user. Sets of one or more pixels 22 in FIG. 3 may be controlled using respective pixel control circuits 40 (sometimes referred to as driving circuits 40 or microdrivers 40). Pixel control circuits 40 may be formed using integrated circuits (e.g., silicon integrated circuits) and/or thin-film transistor circuitry on substrate 26. The thin-film transistor circuitry may include thin-film transistors formed from silicon (e.g., polysilicon thin-film transistors or amorphous silicon transistors) and/or may include thin-film transistors based on semiconducting oxides (e.g., indium gallium zinc oxide transistors or other semiconducting oxide thin-film transistors). Semiconducting oxide transistors such as indium gallium zinc oxide transistors may exhibit low leakage currents and may therefore be advantageous in configurations for display 14 where it is desirable to lower power consumption (e.g., by lowering the refresh rate for the pixels of the display). Configurations for display 14 in which pixel control circuits 40 are each formed from a silicon integrated circuit and a set of thin-film semiconducting oxide transistors may be used if desired.

Pixels 22 may be organized in an array (e.g., an array having rows and columns). Pixel control circuits 40 may be organized in an associated array (e.g., an array having rows and columns). As shown in FIG. 3, pixel control circuits 40 may be interspersed among the array of pixels 22. Pixels 22 and pixel control circuits 40 may be organized in arrays with rectangular outlines or may have outlines of other suitable shapes. There may be any suitable number of rows and columns in each array (e.g., ten or more, one hundred or more, or one thousand or more).

Each pixel 22 may be formed from a light-emitting component such as a light-emitting diode. If desired, each pixel may contain a pair of light-emitting diodes or other suitable number of light-emitting diodes for redundancy. In this type of configuration, the pair of light-emitting diodes in each pixel can be driven in parallel (as an example). In the event that one of the light-emitting diodes fails, the other light-emitting diode will still produce light. Alternatively or in addition, multiple pixel control circuits may be configured to control each pixel. In the event that one of the pixel control circuit fails, the other pixel control circuit will still control the pixel.

Display driver circuitry such as display driver circuitry 20 may be coupled to conductive paths such as metal traces on substrate 26 using solder or conductive adhesive. Display driver circuitry 20 may contain communications circuitry for communicating with system control circuitry over path 24. Path 24 may be formed from traces on a flexible printed circuit or other cable or may be formed using other signal path structures in device 10. The control circuitry may be located on a main logic board in an electronic device in which display 14 is being used. During operation, the control circuitry on the logic board (e.g., control circuitry 16 of FIG. 1) may supply circuitry such as display driver circuitry 20 with information on images to be displayed on display 14. To display the images on display pixels 22, display driver circuitry 20 may supply corresponding image data, control signals, and/or power supply signals to signal lines S. The signal lines provide corresponding image data, control signals, and power to the pixel control circuits 40. Based on the received power, image data, and control signals, the pixel control circuits 40 direct a respective subset of pixels 22 to generate light at desired intensity levels.

Signal lines S may carry analog and/or digital control signals (e.g., scan signals, emission transistor control signals, clock signals, digital control data, power supply signals, etc.). In some cases, a signal line may be coupled to a respective column of pixel control circuits 40. In some cases, a signal line may be coupled to a respective row of pixel control circuits 40. Each pixel control circuit 40 may be coupled to one or more signal lines. Circuitry 20 may be formed on the upper edge of display 14 (as in FIG. 3), on the lower edge of display 14, on the upper and left edges of display 14, on the upper, left, and right edges of display, or any other desired location(s) within display 14.

Display control circuitry such as circuitry 20 may be implemented using one or more integrated circuits (e.g., display driver integrated circuits such as timing controller integrated circuits and associated source driver circuits and/or gate driver circuits) or may be implemented using thin-film transistor circuitry implemented on substrate 26.

Pixels 22 may be organic light-emitting diode pixels or liquid crystal display pixels. Alternatively, pixels 22 in FIG. 3 may be formed from discrete inorganic light-emitting diodes (sometimes referred to as microLEDs). Pixels 22 may include light-emitting diodes of different colors (e.g., red, green, blue). Corresponding signal lines may be used to carry red, green, and blue data. Pixel arrangements of other colors may be used, if desired (e.g., four color arrangements, arrangements that include white pixels, three-pixel configurations with pixels other than red, green, and blue pixels, etc.). To produce different colors, the light-emitting diodes of pixels 22 may be constructed from different materials systems (e.g., AlGaAs for red diodes, GaN multiple quantum well diodes with different quantum well configurations for green and blue diodes, respectively), may be formed using different phosphorescent materials or different quantum dot materials to produce red, blue, and/or green luminescence, or may be formed using other techniques or combinations of these techniques. The light-emitting diodes of pixels 22 may radiate upwards (i.e., pixels 22 may use a top emission design) or may radiate downwards through substrate 26 (i.e., pixels 22 may use a bottom emission design). The light-emitting diodes may have thicknesses between 0.5 and 10 microns and may have lateral dimensions between 2 microns and 100 microns (as examples). Light-emitting diodes with other thicknesses (e.g., below 2 microns, above 2 microns, etc.) and that have other lateral dimensions (e.g., below 10 microns, below 20 microns, above 3 microns, above 15 microns, etc.) may also be used, if desired.

If desired, digital control signals can be provided to circuits 40 (over signal lines S), which may then produce corresponding analog light-emitting drive signals based on the digital control signals. During operation of display 14, each pixel control circuit 40 may supply output signals to a corresponding set of pixels 22 based on the control signals received by that pixel control circuit from display driver circuitry 20.

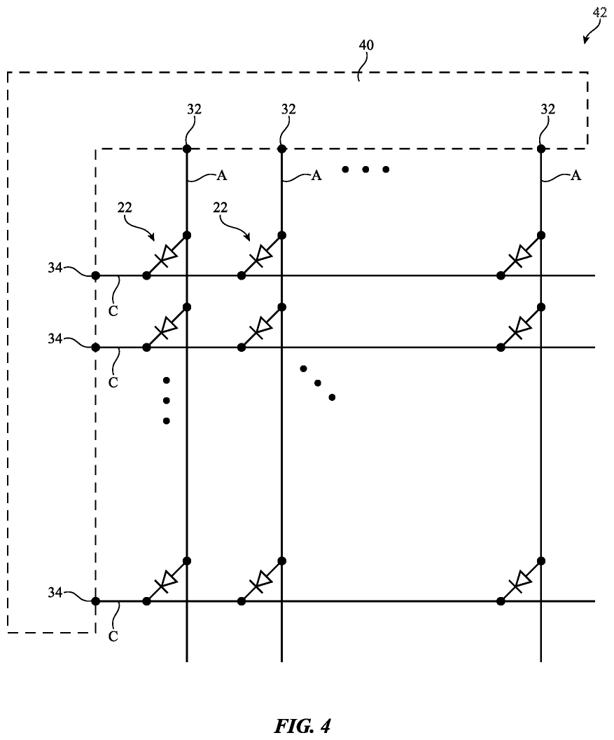

As one example, each pixel control circuit 40 may control a respective local passive matrix 42 of LED pixels 22. FIG. 4 is a schematic diagram of a local passive matrix 42 of LED pixels 22. As shown in FIG. 4, the anode of each LED 22 is coupled to a respective anode contact line A (sometimes referred to as anode contact A or anode line A). The LEDs 22 of each column in the passive matrix are connected to a common anode contact A. The cathode of each LED 22 is coupled to a respective cathode contact line C (sometimes referred to as cathode contact C or cathode line C). The LEDs 22 of each row in the passive matrix are connected to a common cathode contact C.

Pixel control circuit 40 may control the current and voltage provided to each anode line A. The pixel control circuit 40 may also control the voltage provided to each cathode contact line C. In this way, pixel control circuit 40 controls the current through each light-emitting diode 22, which controls the intensity of light emitted by each light-emitting diode. During operation of the passive matrix, pixel control circuit 40 may scan the pixels 22 row-by-row at high speeds to cause each LED 22 to emit light at a desired brightness level. In other words, each pixel in the first row is updated to a desired brightness level, then each pixel in the second row is updated to a desired brightness level, etc.

Pixel control circuit 40 may have first output terminals 32 that are coupled to the anode contact lines A and second output terminals 34 that are coupled to the cathode contact lines C. Pixel control circuit 40 may have one output terminal 32 per anode contact line and one output terminal 34 per cathode contact line, as one example. Using the passive matrix as in FIG. 4 therefore allows pixel control circuit 40 to control 64 light-emitting diodes (e.g., in an 8×8 grid) using only 16 outputs (8 anode output terminals and 8 cathode output terminals).

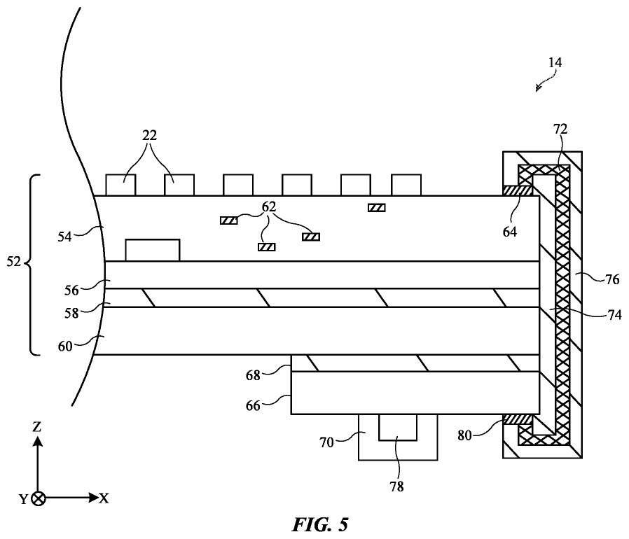

FIG. 5 is a cross-sectional side view of an illustrative display with side-wrapped conductive traces. As shown in FIG. 5, display 14 may include a display panel 52. In the example of FIG. 5, display panel 52 is a microLED display panel with pixels 22 formed from discrete light-emitting diodes (microLEDs) each formed from a crystalline semiconductor die. The pixels 22 are formed on at least one planarization layer 54. The at least one planarization layer 54 includes a plurality of metal layers 62 that form signal lines to provide control and data signals to pixels 22 (e.g., anode lines A in FIG. 4, cathode lines C in FIG. 4, signal lines S in FIG. 3, data lines D in FIG. 2, gate lines G in FIG. 2, etc.). The at least one planarization layer 54 also covers one or more pixel control circuits 40 in the example of FIG. 5.

Planarization layer(s) 54 and pixel control circuit(s) 40 are formed on a substrate 56. Substrate 56 may be formed from polyimide or another desired material. An adhesive layer 58 (e.g., a pressure sensitive adhesive) attaches substrate 56 to an additional substrate 60. Substrate 60 may be formed from polyethylene terephthalate (PET) or another desired material.

Display 14 may include display driver circuitry such as a display driver integrated circuit and/or a timing controller that provides control and data signals to pixels 22 (e.g., through signal lines formed using metal layers 62). Display panel 52 includes contacts 64 on an upper surface of the display panel that receives the control and data signals. Contacts 64 may be electrically connected to various signal lines formed from metal layers 62. The signal lines are used to control pixels 22 during operation of the display.

In some displays, a flexible printed circuit may be attached directly to contacts 64 on an upper surface of display panel 52. The flexible printed circuit may be bent and may connect to a rigid printed circuit board in the electronic device. The flexible printed circuit provides control and data signals to the display panel through contacts 64. This type of arrangement may be less robust and take up more space in the electronic device than desired.

As shown in FIG. 5, side-wrapped conductive traces may be used to electrically connect contacts 64 on an upper surface of display panel 52 to a flexible printed circuit. Flexible printed circuit 66 is attached to a lower surface of substrate 60 (e.g., a lower surface of the display panel) with adhesive layer 68. Adhesive layer 68 may be a pressure sensitive adhesive or another desired type of adhesive.

A system-in-package (SiP) 70 may be mounted to flexible printed circuit 66. The system-in-package may include a display driver integrated circuit 78. Display driver integrated circuit may provide control and data signals for operating pixels 22 to the pixels via side-wrapped conductive traces 72. The signals from display driver integrated circuit 78 are conveyed to pixels 22 through flexible printed circuit 66, contacts 80 on flexible printed circuit 66, side-wrapped traces 72, contacts 64 on display panel 52, and metal layers 62.

A first insulating layer 74 may be interposed between conductive traces 72 and an edge of display panel 52. A second insulating layer 76 may cover conductive traces 72 such that the conductive traces are interposed between the first and second insulating layers 74 and 76. Conductive traces 72 may conform to the edge of display panel 52 and therefore may be referred to as being conformally wrapped around the edge of the display panel. First insulating layer 74 may conform to the edge of display panel 52. Conductive traces 72 may conform to first insulating layer 74 (and, correspondingly, display panel 52). There is no air gap between conductive traces 72 and the edge of display panel 52.

There are many advantages to the arrangement of FIG. 5. The side-wrapped conductive traces occupy a minimal volume within the electronic device (where space is at a premium). The side-wrapped conductive traces allow for a narrow border to the display. The side-wrapped conductive traces may be easily formed on multiple edges of the display panel, improving IR drop and corresponding power delivery. The side-wrapped conductive traces may be robust during the manufacturing process and during drop events in real-time use.

The side-wrapped conductive traces of FIG. 5 may also be an effective signal routing method for a wide variety of display types. For example, the side-wrapped conductive traces may be used in display panels with organic light-emitting diode (OLED) pixels, microLED pixels (as in FIG. 5), or other types of pixels. Additionally, the side-wrapped conductive traces may provide effective and robust electrical connections in non-planar displays (e.g., flexible and/or foldable displays that are configured to bend along one or more bend axes, curved displays with one or more curved portions, displays with compound curvature, etc.).

To deposit traces 72, a very precise deposition of conductive material may be required. For example, traces 72 may be deposited (e.g., printed) on contacts 64, contacts 80, and insulating layer 74 with micron-level resolution. The traces may be printed with widths that are less than 2 microns, less than 1 micron, etc. The traces may be separated by gaps that are less than 5 microns, less than 3 microns, etc. The traces may be printed on curved surfaces (e.g., surfaces with convex curvature, compound curvature, etc.), stepped surfaces, etc. while maintaining satisfactory electrical continuity.

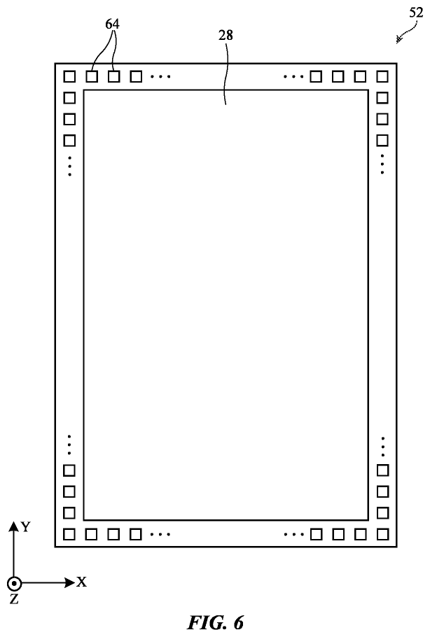

FIG. 6 is a top view of the display panel of FIG. 5. As shown in FIG. 6, contacts 64 (that are each connected to a respective side-wrapped conductive trace 72) may be distributed around the entire periphery of display panel 52. Display panel 52 includes pixel array 28 in a central portion of the display panel. The display panel has first and second (e.g., top and bottom) opposing edges connected by third and fourth (e.g., left and right) opposing edges (e.g., when viewed from above as in FIG. 6). Contacts 64 may optionally be interposed between the pixel array and the first edge, between the pixel array and the second edge, between the pixel array and the third edge, and between the pixel array and the fourth edge. The side-wrapped conductive traces 72 may easily be applied to all four edges of the display panel, so there is no substantial increase in manufacturing cost or complexity to provide contacts along all four edges. Providing contacts around the periphery of the display panel in this manner may improve IR drop and corresponding power delivery for the display. Providing contacts around the periphery of the display panel in this manner may also prevent the crowding (and fanout complexity) of corresponding signal lines.

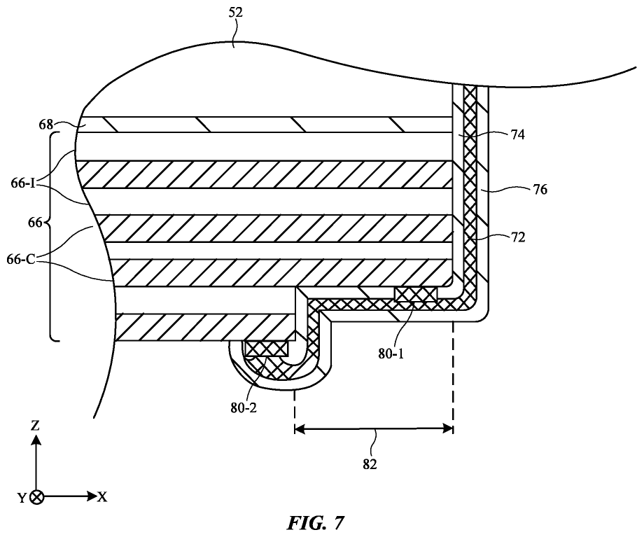

If desired, a multi-step interface may be provided between conductive traces 72 and flexible printed circuit 66. FIG. 7 is a cross-sectional side view of a flexible printed circuit with a multi-step interface. As shown in FIG. 7, flexible printed circuit 66 includes a plurality of alternating insulating layers 66-I (e.g., formed from polyimide or another desired insulating material) and a plurality of conductive layers 66-C (e.g., formed from copper or another desired conductive material). Each adjacent pair of one insulating layer and one conductive layer may be considered a respective layer of the flexible printed circuit. A first plurality of contacts 80-1 are formed on a first conductive layer 66-C while a second plurality of contacts 80-2 are formed on a second conductive layer 66-C. The conductive layer with contacts 80-2 has an edge that is shifted by a distance 82 from the edge of the rest of the flexible printed circuit (e.g., the conductive layer with contacts 80-1). This exposes a portion of the conductive layer with contacts 80-1 to allow for electrical connections of traces 72 to two conductive layers of the flexible printed circuit (instead of just the bottom conductive layer of the flexible printed circuit).

Some of conductive traces 72 are electrically connected to contacts 80-1 while other conductive traces 72 are electrically connected to contacts 80-2. The precise deposition techniques used for conductive traces 72 may enable the traces to maintain continuity when crossing the right angles formed by the multi-step interface of the flexible printed circuit.

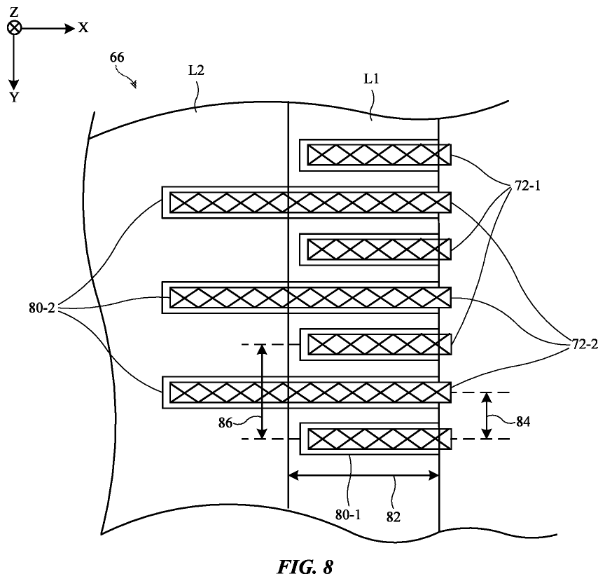

FIG. 8 is a bottom view of the multi-step interface of the flexible printed circuit in FIG. 7. As shown, a plurality of contacts 80-1 are formed on a first layer (L1) of the flexible printed circuit (with a corresponding conductive layer 66-C and insulating layer 66-I). Contacts 80-1 may be electrically connected to patterned portions of the corresponding conductive layer 66-C. Contacts 80-2, meanwhile, are formed on a second layer (L2) of the flexible printed circuit (with a corresponding conductive layer 66-C and insulating layer 66-I). The edge of layer L2 is shifted from the edge of layer L1 by distance 82. Contacts 80-2 may be electrically connected to patterned portions of the corresponding conductive layer 66-C.

Traces 72-1 are electrically connected to contacts 80-1 on layer L1. Specifically, traces 72-1 are electrically connected to a portion of layer L1 that is exposed due to the shifted edge of layer L2. Traces 72-2 pass through the exposed portion of layer L1 and are electrically connected to contacts 80-2 on layer L2. Traces 72 may be separated by a center-to-center pitch 84. The magnitude of pitch 84 may be greater than 3 microns, greater than 5 microns, greater than 10 microns, greater than 20 microns, greater than 50 microns, less than 3 microns, less than 5 microns, less than 10 microns, less than 20 microns, less than 50 microns, between 5 microns and 15 microns, etc. Contacts 80-1 may be separated by a center-to-center pitch 86. The magnitude of pitch 86 may be greater than 5 microns, greater than 10 microns, greater than 20 microns, greater than 50 microns, less than 5 microns, less than 10 microns, less than 20 microns, less than 50 microns, between 10 microns and 30 microns, between 15 microns and 25 microns, etc. Contacts 80-2 may be separated by a center-to-center pitch that is the same as for contacts 80-1 or that is different than for contacts 80-2 (e.g., any of the magnitudes listed above in connection with contacts 80-1). The center-to-center pitch of contacts 80-1 and/or 80-2 may be greater than the center-to-center pitch of traces 72. The center-to-center pitch of contacts 80-1 and/or 80-2 may be greater than the center-to-center pitch of traces 72 by at least 20%, at least 50%, at least 75%, at least 100%, between 50% and 150%, etc.

With the multi-step arrangement of FIGS. 7 and 8, conductive traces 72 with a small center-to-center pitch (for high resolution) may be electrically connected to corresponding contacts while maintaining satisfactory manufacturing tolerance for the contacts 80 on the flexible printed circuit.

The example in FIGS. 7 and 8 of the flexible printed circuit having contacts on two layers (e.g., a two-step arrangement) is merely illustrative. If desired, the flexible printed circuit may have contacts on three layers (e.g., a three-step arrangement), may have contact on four layers, may have contacts on more than four layers, etc.

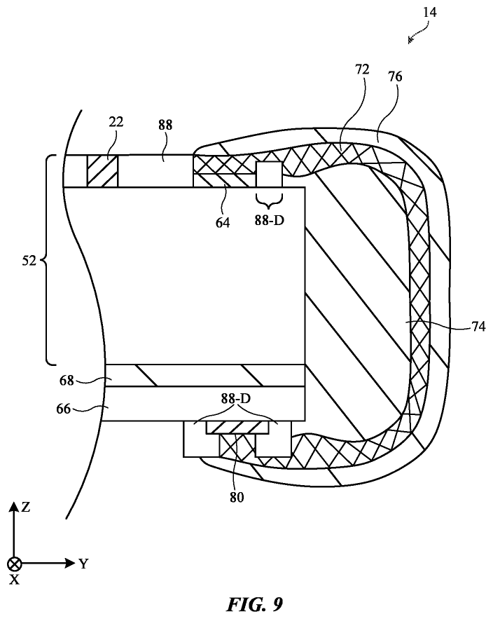

FIG. 9 is a cross-sectional side view of an illustrative display with side-wrapped conductive traces. FIG. 9 shows how insulating layer 74 may be provided with a curved surface (e.g., having convex curvature). This may allow for easier deposition of conductive traces 72 on the insulating layer. If desired, the edge(s) of display panel 52 with side-wrapped traces may also have curvature (e.g., convex curvature) to promote curvature in insulating layer 74.

FIG. 9 also shows planarization layer 88. In the portion of display panel 52 with pixel array 28, planarization layer 88 may be coplanar with (and conform to the edge surfaces of) pixels 22. Planarization layer 88 may also serve as a dam structure for insulating layer 74. As shown in FIG. 9, an additional portion of planarization layer 88 forms dam structure 88-D. The insulating layer 74 is then deposited adjacent to a side of dam structure 88-D. Dam structure 88-D is therefore formed from the same material (and during the same manufacturing step) as planarization layer 88 in the pixel array. Dam structures 88-D may also be formed on flexible printed circuit 66. These dam structures may be formed from the same material as planarization layer 88 in the pixel array.

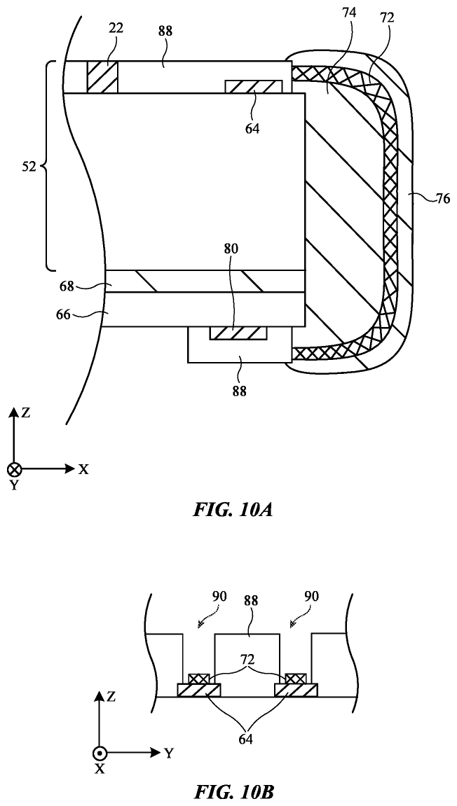

In another possible arrangement, shown in FIGS. 10A and 10B, the planarization layer 88 defines channels for conductive traces 72. As shown in FIG. 10A, planarization layer 88 extends over the edge of the display panel with contacts 64. The planarization layer 88 may define a plurality of channels, with each channel containing a respective trace 72. As shown in FIG. 10B, channels 90 are defined by planarization layer 88 over contacts 64. A respective trace 72 is then formed in each channel. As shown in FIG. 10A, the traces 72 may exit the channels at the edge of the display panel and continue along insulating layer 74. A planarization layer 88 may also be formed over the edge of flexible printed circuit 66 and contacts 80 to define channels in a similar manner.

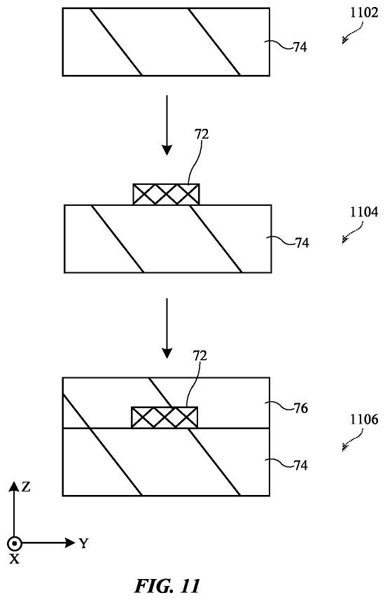

FIG. 11 is a flowchart of an illustrative method for forming conductive traces between first and second insulating layers. First, at step 1102, a first insulating layer 74 may be formed (e.g., over one or more of the top of display panel 52, the edge of display panel 52, the edge of adhesive layer 68, the edge of flexible printed circuit 66, the bottom of flexible printed circuit 66, etc.). Next, at step 1104, one or more conductive traces 72 are formed on insulating layer 74. Finally, at step 1106, a second insulating layer 76 is formed over traces 72 and insulating layer 74. The second insulating layer 76 conforms to traces 72 and insulating layer 74.

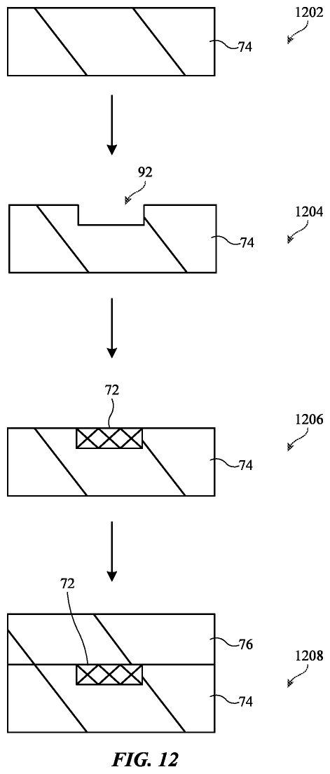

FIG. 12 is a flowchart of another illustrative method for forming conductive traces between first and second insulating layers. First, at step 1202, a first insulating layer 74 may be formed (e.g., over one or more of the top of display panel 52, the edge of display panel 52, the edge of adhesive layer 68, the edge of flexible printed circuit 66, the bottom of flexible printed circuit 66, etc.). Next, at step 1204, one or more channels 92 are formed in the upper surface of insulating layer 74 (e.g., via etching). The one or more channels may each be sized to contain a respective conductive trace 72. At step 1206, one or more conductive traces 72 are formed on insulating layer 74 within respective channels 92. The conductive traces may be contained within channels such that the upper surface of traces 72 do not extend past the upper surface of insulating layer 74. In the example of FIG. 12, the upper surface of traces 72 are coplanar with the upper surface of insulating layer 74. This arrangement results in a flat surface with portions defined by traces 72 and portions defined by insulating layer 74. Finally, at step 1208, a second insulating layer 76 is formed over traces 72 and insulating layer 74. Forming the conductive traces in channels as in FIG. 12 may improve the robustness of the conductive traces (e.g., during a drop event).

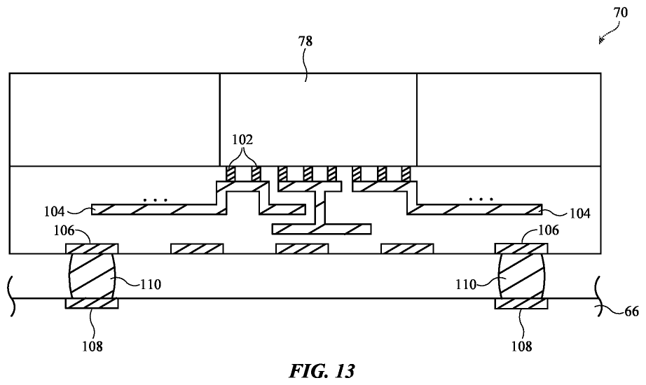

FIG. 13 is a cross-sectional side view of an illustrative system-in-package (SiP) that may be included in display 14. As shown in FIG. 13, SiP 70 includes display driver integrated circuit (DDIC) 78. The DDIC has a plurality of output contacts 102 that are electrically connected to redistribution layers 104. The redistribution layers 104 (sometimes referred to as conductive redistribution layers 104) route signals between contacts 102 (connected to DDIC 78) and contacts 106 (which are connected to flexible printed circuit 66). As shown in FIG. 13, contacts 106 of SiP 70 may be connected (e.g., mechanically and electrically) to corresponding contacts 108 in flexible printed circuit 66 by conductive attachment structures 110. Conductive attachment structures 110 may be formed from solder, as one example.

The contacts 106 (for the SiP-to-flex interface) may be larger in size (area) and/or have a larger pitch than the DDIC contacts 102. The total area of each contact 106 may be at least 50% greater than the total area of each contact 102, at least 100% greater than the total area of each contact 102, at least 150% greater than the total area of each contact 102, at least 200% greater than the total area of each contact 102, at least 400% greater than the total area of each contact 102, etc. The center-to-center pitch of contacts 106 may be at least 20% greater than the center-to-center pitch of contacts 102, at least 50% greater than the center-to-center pitch of contacts 102, at least 100% greater than the center-to-center pitch of contacts 102, at least 200% greater than the center-to-center pitch of contacts 102, etc.

In addition to the DDIC 78, SiP 70 may include additional integrated circuits and/or other passive display components (e.g., capacitors, resistors, etc.).

Any of the conductive components herein (e.g., traces 72 or other desired components) may comprise nanoparticles and/or nanowires. In one example, a conductive component (e.g., traces 72) may comprise both nanoparticles (e.g., spherical particles) and nanowires (e.g., rods with a diameter and a length that is more than five times the diameter). Due to increased contact/fused points, including both nanowires and nanoparticles may decrease resistance at low sintering temperatures relative to a conductive filler without nanowires. Traces 72 may be formed from nanoparticles and/or nanowires formed from silver or another desired material. In one example, a single trace 72 may include both silver nanowires and silver nanoparticles.

The foregoing is merely illustrative and various modifications can be made by those skilled in the art without departing from the scope and spirit of the described embodiments. The foregoing embodiments may be implemented individually or in any combination.

What is claimed is:

1. An electronic device comprising:
a display panel with an upper surface, a lower surface, and an edge surface that extends between the upper surface and the lower surface, wherein the display panel includes an array of display pixels on the upper surface;
first conductive contacts on the upper surface;
a flexible printed circuit that is attached to the lower surface;
second conductive contacts on the flexible printed circuit; and
conductive traces that conformally wrap around the edge surface of the display panel to electrically connect the first conductive contacts to the second conductive contacts.

2. The electronic device defined in claim 1, wherein there is no air gap between the conductive traces and the edge surface of the display panel.

3. The electronic device defined in claim 1, further comprising:
a first insulating layer that conforms to the edge surface of the display panel, wherein the conductive traces are formed on the first insulating layer.

4. The electronic device defined in claim 3, further comprising:
a second insulating layer that covers the conductive traces, wherein the conductive traces are interposed between the first insulating layer and the second insulating layer.

5. The electronic device defined in claim 3, further comprising:
a planarization layer having a first portion formed within the array of display pixels and a second portion that serves as a dam structure for the first insulating layer.

6. The electronic device defined in claim 1, further comprising:
a system-in-package mounted on the flexible printed circuit, wherein the system-in-package includes a display driver integrated circuit that is configured to provide signals to the array of display pixels using the conductive traces.

7. The electronic device defined in claim 6, wherein the system-in-package comprises:
a plurality of redistribution layers;
third conductive contacts that electrically connect the display driver integrated circuit to the plurality of redistribution layers; and
fourth conductive contacts that electrically connect the redistribution layers to the flexible printed circuit.

8. The electronic device defined in claim 7, wherein the third conductive contacts have a first center-to-center pitch and wherein the fourth conductive contacts have a second center-to-center pitch that is greater than the first center-to-center pitch.

9. The electronic device defined in claim 1, wherein the upper surface of the display panel has first and second opposing edges connected by third and fourth opposing edges and wherein the first conductive contacts are formed along the first, second, third, and fourth edges.

10. The electronic device defined in claim 1, wherein the flexible printed circuit includes a first layer with a first edge and a second layer with a second edge, wherein the first edge is shifted relative to the second edge, and wherein the first conductive contacts comprise a first subset of conductive contacts on the first layer and a second subset of conductive contacts on the second layer.

11. The electronic device defined in claim 10, wherein the conductive traces have a first center-to-center pitch, wherein the first subset of conductive contacts on the first layer has a second center-to-center pitch that is greater than the first center-to-center pitch, and wherein the second subset of conductive contacts on the second layer has a third center-to-center pitch that is greater than the first center-to-center pitch.

12. The electronic device defined in claim 1, further comprising:
a planarization layer having a first portion formed within the array of display pixels and a second portion that defines a plurality of channels for the conductive traces.

13. The electronic device defined in claim 1, further comprising:
an insulating layer that conforms to the edge surface of the display panel, wherein the insulating layer defines a plurality of channels and wherein each channel contains a respective conductive trace of the conductive traces.

14. The electronic device defined in claim 1, wherein the conductive traces comprise silver nanoparticles and silver nanowires.

15. An electronic device comprising:
a display panel with an array of display pixels;
a flexible printed circuit that is attached to the display panel, wherein the flexible printed circuit has a multi-step edge, wherein the multi-step edge comprises a first layer and a second layer formed over the first layer, wherein the first layer has a first edge, and wherein the second layer has a second edge that is shifted relative to the first edge; and
conductive traces that wrap around an edge of the display panel to electrically connect the display panel to the flexible printed circuit, wherein a first subset of the conductive traces is electrically connected to the first layer of the flexible printed circuit and wherein a second subset of the conductive traces is electrically connected to the second layer of the flexible printed circuit.

16. The electronic device defined in claim 15, further comprising:
a layer of pressure sensitive adhesive that attaches the flexible printed circuit to a lower surface of the display panel.

17. The electronic device defined in claim 15, wherein the conductive traces have a first center-to-center pitch, wherein the first subset of the conductive traces is electrically connected to conductive contacts on the first layer having a second center-to-center pitch, and wherein the second center-to-center pitch is at least 50% greater than the first center-to-center pitch.

18. The electronic device defined in claim 15, wherein the first subset of the conductive traces passes through an exposed portion of the second layer to reach the first layer.

19. The electronic device defined in claim 18, wherein the second subset of the conductive traces is electrically connected to the exposed portion of the second layer.

20. An electronic device comprising:
a display panel with an array of display pixels;
a flexible printed circuit that is attached to the display panel; and
conductive traces that wrap around an edge of the display panel to electrically connect the display panel to the flexible printed circuit; and
a system-in-package mounted on the flexible printed circuit, wherein the system-in-package includes a display driver integrated circuit that is configured to provide signals to the array of display pixels using the conductive traces.

21. The electronic device defined in claim 20, wherein the system-in-package comprises:
a plurality of redistribution layers;
first conductive contacts that electrically connect the display driver integrated circuit to the plurality of redistribution layers; and
second conductive contacts that electrically connect the redistribution layers to the flexible printed circuit.

22. The electronic device defined in claim 20, wherein the first conductive contacts have a first center-to-center pitch and wherein the second conductive contacts have a second center-to-center pitch that is greater than the first center-to-center pitch.
